(19) United States
(12) Patent Application Publication
(10) Pub. No.: US 2016/0242304 A1
(43) Pub. Date: Aug. 18, 2016

(54) WIRE STORAGE DEVICE

(71) Applicant: JUI-FENG HSU, NEW TAIPEI CITY (TW)

(72) Inventors: JUI-FENG HSU, NEW TAIPEI CITY (TW); WEI-BO ZHEN, NEW TAIPEI CITY (TW)

(21) Appl. No.: 14/684,312

(22) Filed: Apr. 10, 2015

(30) Foreign Application Priority Data
Feb. 17, 2015 (TW) 104202769

(51) Int. Cl. H05K 5/02

(52) U.S. Cl. CPC H05K 5/0247

(57) ABSTRACT

A wire storage device enabling users freely store wires without the prior art problem of intertwining. It includes a main body, a containing area, a fixing slot, and a fixing piece. A groove is positioned at the outer side of the main body, and said groove surrounds said main body all the way around. A containing area is positioned at the inner side of said main body, and a port is positioned at the edge of said containing area, said port connecting said groove with said containing area. A fixing slot is positioned at one side and a fixing piece is positioned at another side of said main body. While one end of the wire is placed inside said containing area, it enters into said groove through said port, and can be wound along said groove. After the wire is received/stored, it wouldn't be intertwined with another object, and would be carried and stored conveniently.

### FIELD OF THE INVENTION

The present invention relates to a wire storage device, particularly to a device that stores a wire via winding.

### DESCRIPTION OF THE RELATED ART

While electronic products have brought considerable conveniences into human life, at the same time, the dependency of people on electronic product have also increased. The surroundings of these electronic products are full of wires, such as earphone cables, communication cables etc.

In the past, the way of storing wires was to put the wire into a bag after arranging the wire, or to use another wire, or to bind the wire via a rubber rope. However, if another bag is used to load the wire, the wire would frequently rip the bag and come out; and therefore, the wire needs to be re-arranged again to overcome the problem of intertwining.

In the case of arranging and storing the wire via binding; not only the problem of intertwining of the wire would still occur easily, but also the wire can easily be intertwined and tangled with other objects. As a result, binding alone is not enough for storing a wire. The wire also needs to be placed in a bag in order to prevent contact with other objects.

In the light of the above given information, besides the earphone cables that are commonly carried and used, people can also carry charger wires, signal cables etc. wires on themselves; and therefore, nowadays, the way of arranging and conveniently carrying these wires is an important problem to be solved.

### SUMMARY OF THE INVENTION

In order to overcome the drawbacks of the prior art about storing wires, the present invention provides a wire storage device, which enables users freely store wires without the prior art problem of intertwining.

The present invention is a wire storage device, comprising a main body, a containing area, a fixing slot, and a fixing piece. A groove is positioned at the outer side of the main body, and said groove surrounds said main body all the way around. A containing area is positioned at the inner side of said main body, and a port is positioned at the edge of said containing area, said port connecting said groove with said containing area. A fixing slot is positioned at one side and a fixing piece is positioned at another side of said main body. While one end of the wire is placed inside said containing area, it enters into said groove through said port, and can be wound along said groove.

Since all of the wire is wound around the groove, therefore it wouldn't be entangled with other objects and thus it is convenient for tidying up the wire. Moreover, the flat design makes it easy to carry and store wires, and it can be placed at the edges of handbags or suitcases.

Moreover, the containing area also comprises a rechargeable battery. As a result, it turns into a carry-on power bank.

Moreover, a foot stool is also pin jointed onto the main body. As a result, the whole body can be placed in standing position, and also can be used for supporting other items/products.

Moreover, a base is pin jointed at the other side of the main body opposite to said foot stool. This can be used as a base for phones or mobile devices.

Moreover, a foot stool receiving slot and a base receiving slot are positioned on the main body. In this way, the foot stool and the base can be received and stored on the main body.

Moreover, the groove bottom can become stair-shaped. In this way, while the wire is being wound, it can be done in an even more orderly fashion, so that intertwining problem wouldn't occur.

Moreover, a wire end storage piece is positioned on said containing area in order to fix the position of the wire end.

Moreover, a wire end fixing slot is dented inwards from outside said main body in order to fasten an end of the wire.

Also, the wire storage device group of the present invention can be formed by putting more than one wire storage devices on top of each other, wherein the fixing piece of a wire storage device is plugged into the fixing slot of another wire storage device. In this way, the user can conveniently store different kinds of wires, and by means of storing different wires in a unified manner, it improves the convenience of storage.

After seeing the figures and the detailed description of the embodiments given below, persons having ordinary skill in the related technical field would understand other purposes and technical methods and implementation pattern of the present invention better.

### BRIEF DESCRIPTION OF THE DRAWINGS

FIG. 1 is a schematic view of an embodiment of the present invention during use.

FIG. 2 is a three dimensional schematic view of an embodiment of the present invention.

FIG. 2A is a three dimensional view of the main bodies in elliptic/oval shape and placed on top of each other.

FIG. 3 is a schematic cross-section view of the AA section given in FIG. 2.

FIG. 4 is a schematic view of an action, by which two wire storage device groups combine into one wire storage device group.

FIG. 4A is a three dimensional schematic view, wherein the fixing slot and the fixing piece are in different positions.

FIG. 5 is a three dimensional schematic view of the embodiment shown in FIG. 4.

FIG. 6 is a schematic cross-section view of the BB section given in FIG. 5.

FIG. 7 is a schematic cross-section view of the stair-shaped groove bottom.

FIG. 8 is a three dimensional schematic view of an action of combining the battery.

FIG. 8A is a three dimensional schematic view from another angle showing the combined battery.

FIG. 9 is a three dimensional schematic view incorporating a foot stool.

FIG. 10 is a three dimensional schematic view incorporating a base.

FIG. 11 is a schematic side view showing the placement of the device.

FIG. 12 is a three dimensional schematic view incorporating a wire end storage piece.

FIG. 13 is a three dimensional schematic view incorporating another kind of wire end storage piece.

FIG. 14 is a three dimensional schematic view showing the placement of the wire end fixing slot.

FIG. 15 is a three dimensional schematic view showing the placement of the wire end at the wire end fixing slot.

FIG. 16 shows formation of a single wire storage device group by means of combining two wire storage device groups of different sizes.

FIG. 17 is a three dimensional schematic view incorporating a wire end storage piece and a wire end fixing slot.

FIG. 18 is a three dimensional schematic view of the square-shaped main body.

FIG. 19 is a three dimensional schematic view from another side of the main body shown in FIG. 18.

FIG. 20 is a schematic view of the action, which combines the square-shaped main body with the circular main body.

FIG. 21 is a three dimensional schematic view incorporating a blocking piece.

FIG. 22 is a schematic cross-section view showing the storage/collection of a wire.

FIG. 23 is a schematic view of another mode used for storage/collection of a wire.

FIG. 23A is a schematic view of a situation where the wire is received and fixed by using a C-shaped buckle.

FIG. 24 is a three dimensional schematic view showing the position of a shallow groove.

FIG. 25 is a three dimensional schematic view showing the winding and placement of a wire on a main body comprising a shallow groove.

FIG. 26 is a three dimensional schematic view of FIG. 25 from another angle.

FIG. 27 is a schematic view showing the wire passing through the main body after being pulled open.

FIG. 28 is a three dimensional schematic view wherein the main body comprises two ports.

FIG. 29 is a three dimensional schematic view wherein the main body comprises three ports.

FIG. 30 is a schematic view incorporating the use of a fixed cover when the wire is wound on the main body.

### DETAILED DESCRIPTION OF THE PREFERRED EMBODIMENTS

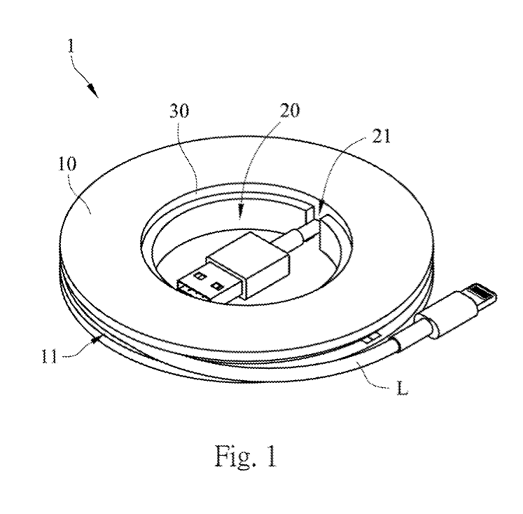

According to FIGS. 1 to 3, the wire storage device 1 of the present embodiment comprises a main body 10, a containing area 20, a fixing slot 30, and a fixing piece 40.

Within this structure, a groove 11 is positioned at the outer side of the main body 10. This groove 11 surrounds the main body 10 all the way around. A wire can be wound around the main body 10 along this groove 11. The containing area 20 is positioned at the inner side of said main body 10. Moreover, a port 21 is positioned at the edge of said containing area 20, and this port 21 connects said groove 11 with said containing area 20. One end of the wire L can be placed within said containing area 20, and it also can enter into said groove 11 through said port 21 and can be wound via the groove 11. The fixing slot 30 is positioned at one side of said main body 10. And the fixing piece 40 is positioned at the other side of the main body 10.

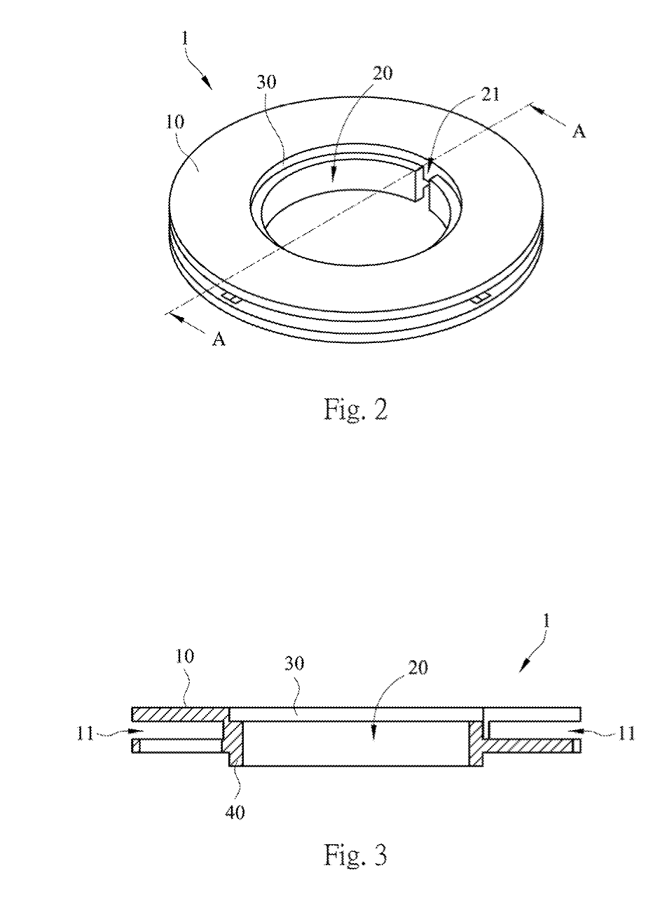

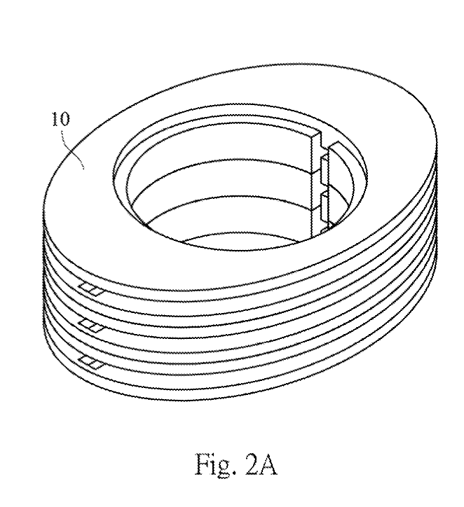

According to the information given above, at least one end of wire L is restricted within the inner part of this embodiment, and also the wire can be wound via the groove 11; and as a result, the wire L would be restricted by the groove 11 to this position. Moreover, since the wire L is protected within the main body 10, it can not be intertwined with another object, and thus the embodiment has the advantage of convenient storage and carriage. In this way, the present embodiment overcomes the intertwining problem that occurs easily in the prior art technique. Moreover, the main body 10 can also have an oval outer shape as shown in FIG. 2A, which also wouldn't prevent them from being placed on top of each other.

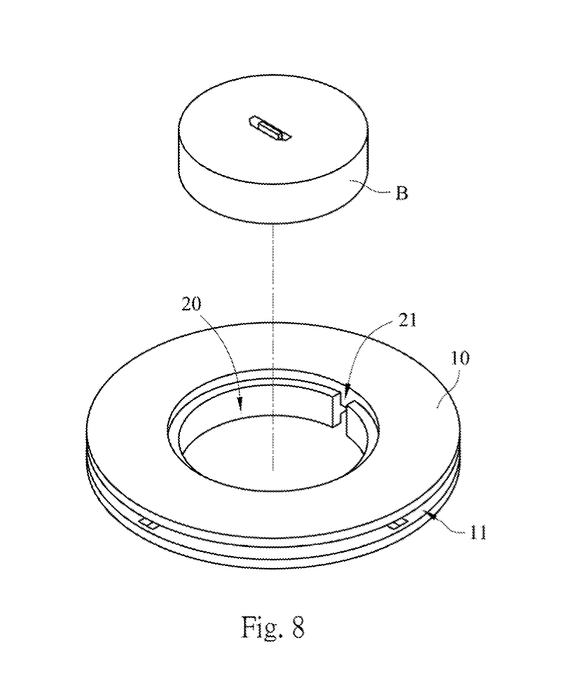

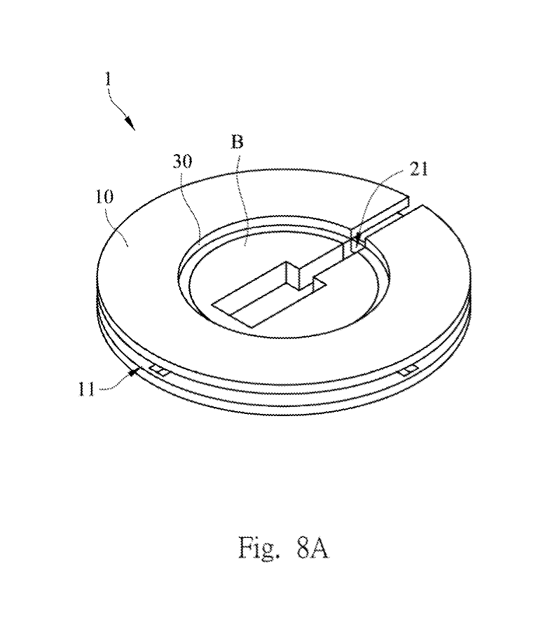

According to FIG. 8, a rechargeable battery B is also incorporated into the containing area 20. This rechargeable battery B is movably installed within said containing area 20, and when the device is required to be charged, the wire can be connected to the port found on said rechargeable battery B in order to start the charging operation. Besides, the outer shape of this rechargeable battery B can correspond to the groove body in which the end of the wire L would be placed (i.e. see FIG. 8A), and thus has the advantage of supporting the fixing place of the wire L end.

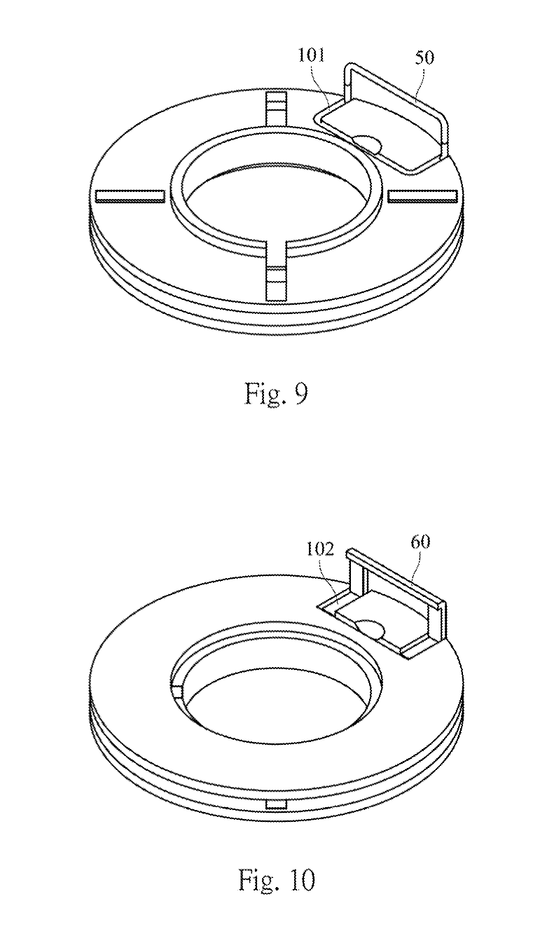

According to FIGS. 9-11, a foot stool 50 is also pin jointed to the main body 10, and when the foot stool 50 is unfolded, it provides standing support for the main body 10, so that it provides supporting place for other objects. Also, the foot stool 50 has a flexible design, which provides a better supporting effect.

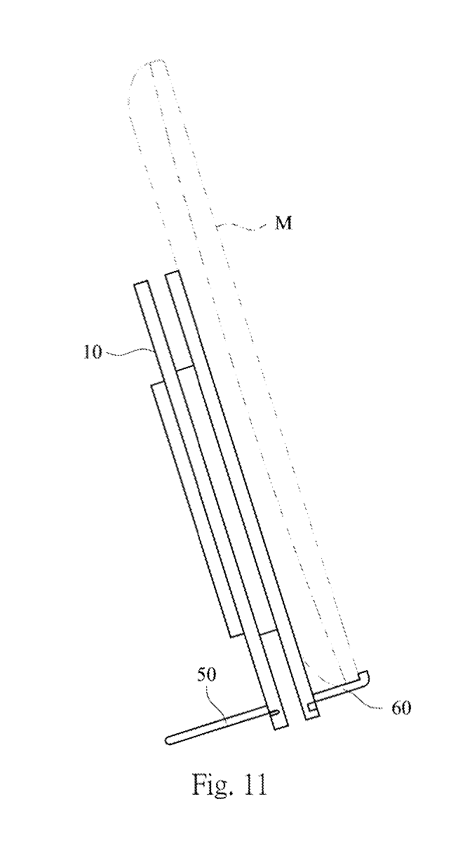

Furthermore, a base 60 is pin jointed on the opposite side of the foot stool 50. When said base 60 is unfolded, it can be used for placing objects/items, such as electronic devices M, so that the electronic device M would appear standing as shown in FIG. 11.

Moreover, a foot stool receiving slot 101 and a base receiving slot 102 can also be positioned on the main body 10. So that, when the foot stool 50 and the base 60 are not used, the foot stool 50 and the base 60 can be received/stored within the main body 10.

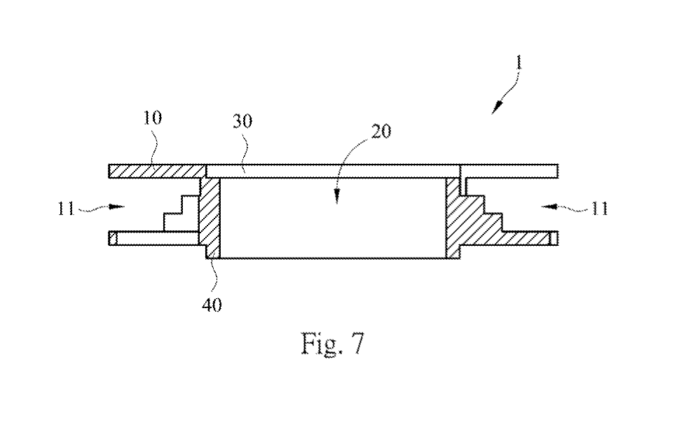

Moreover, according to FIG. 7, the groove 11 bottom can be stair-shaped. By means of the stair-shaped setup, while the wire is being wound, it can be arranged in an easier and smoother way. As a result, the wire L would be prevented from occupying unnecessary space, and thus some part of the wire L being left out of the groove 11 due to being arranged in a wrong manner and getting intertwined during winding.

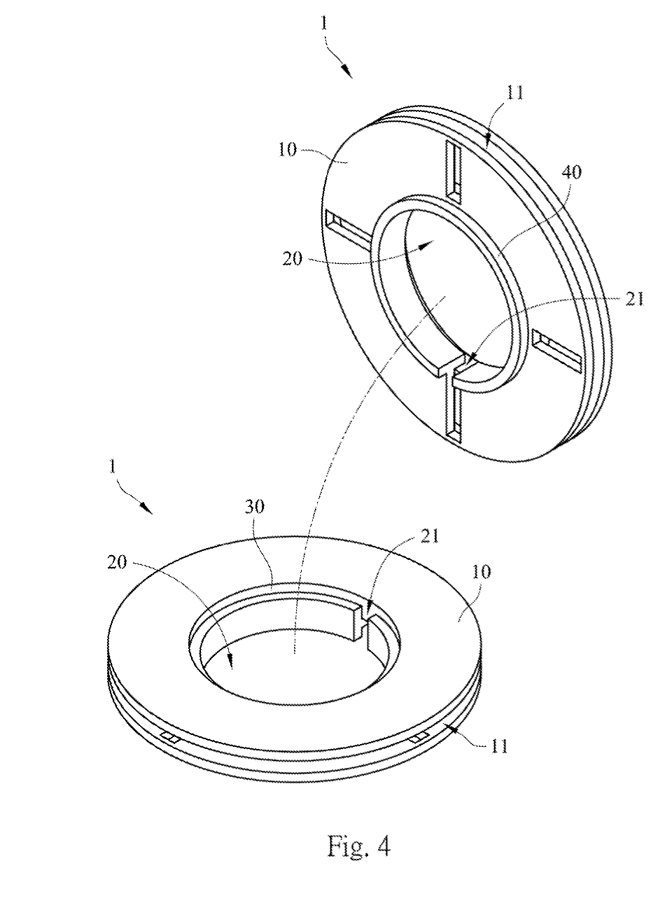

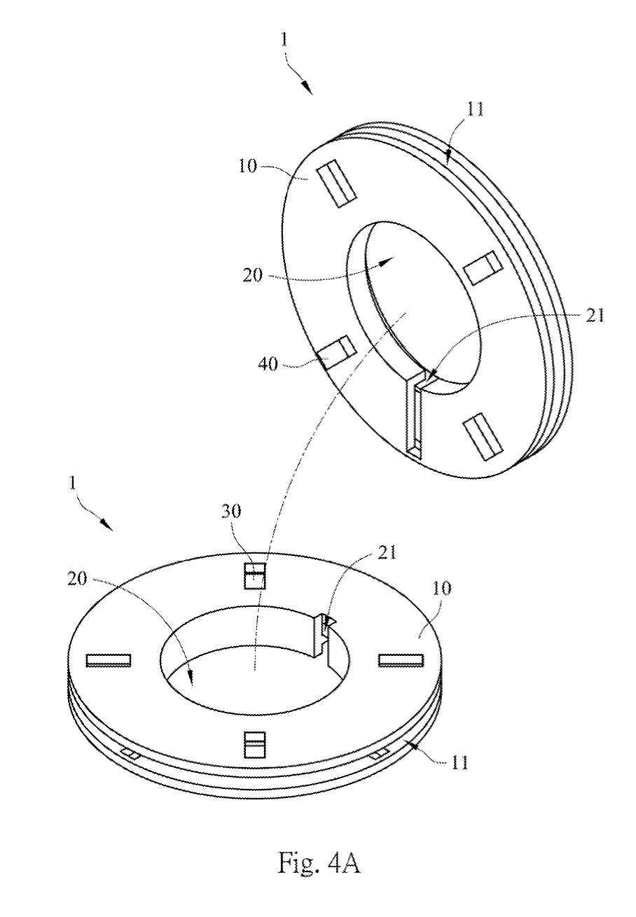

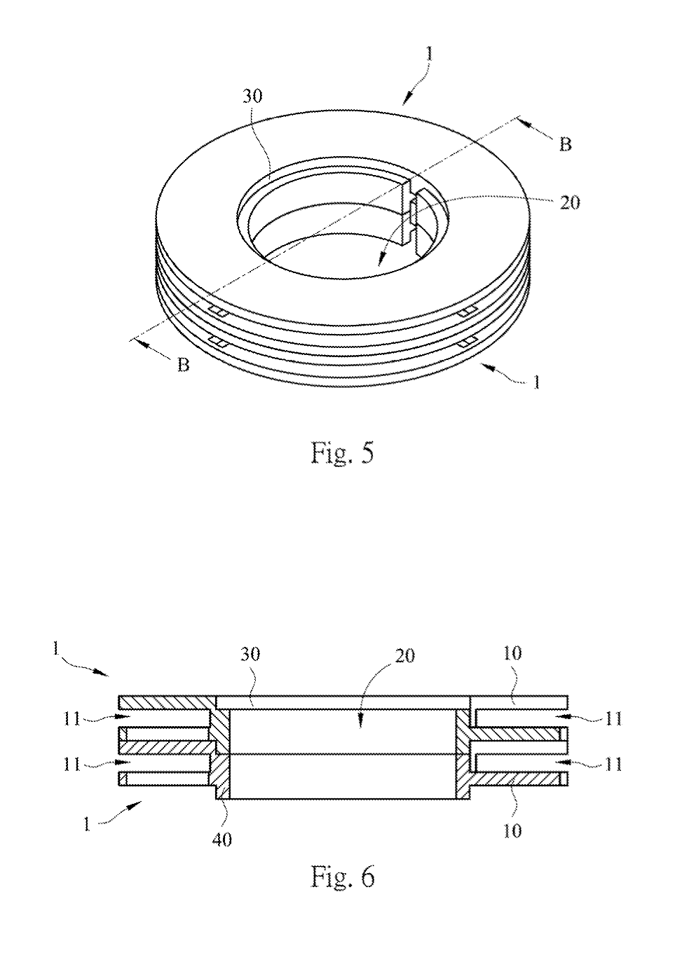

According to FIGS. 4 to 6, a wire storage device group is shown, which is formed of more than one wire storage devices 1 put on top of each other, wherein the fixing piece 40 of a wire storage device 1 is plugged into the fixing slot 30 of another wire storage device 1. After plugging, the devices form a tight fit and thus the two wire storage devices 1 are combined, so that more than one wires L can be received/stored and also the control is unified and concentrated. As a result, independent operation of each device, which would cause complications during receiving, would be avoided.

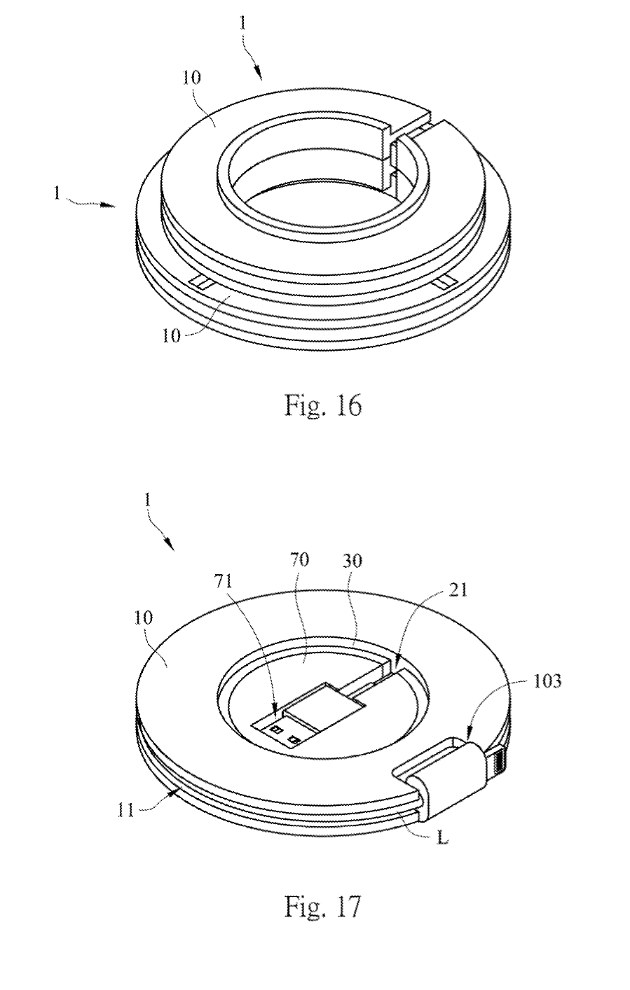

Also, as shown in FIG. 4A, the fixing piece 40 and the fixing slot 30 only need to correspond to each other and have identical sizes, and are not restricted to the position shown in FIG. 1. According to FIG. 16, the sizes of the wire storage devices 1 can be different, and the only requirement is the fixing piece 40 and the fixing slot 30 being positioned at locations corresponding to each other and fitting with each other.

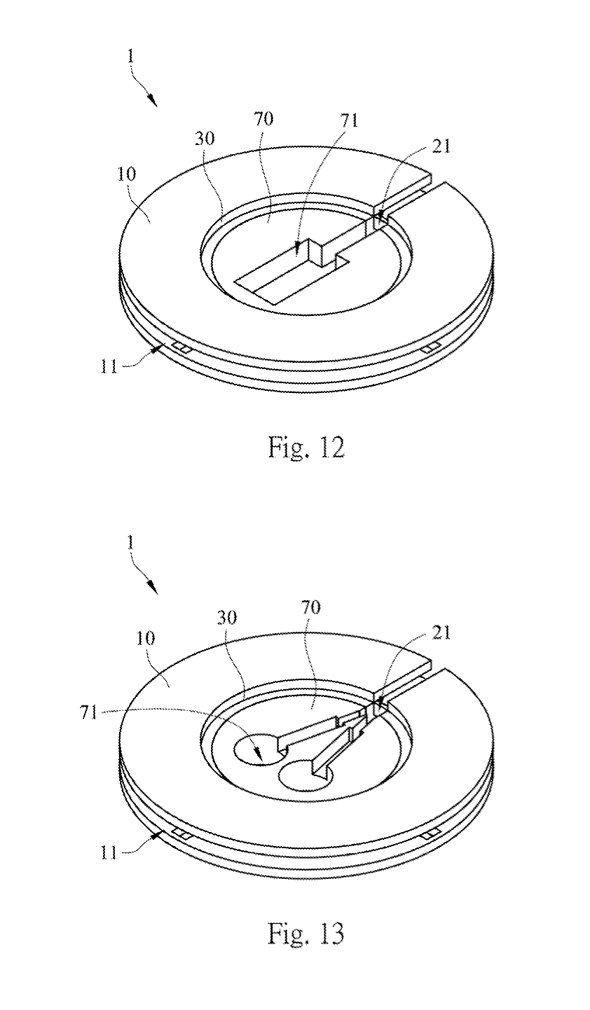

Besides, as shown in FIG. 12 and FIG. 13, a wire end receiving/storage piece 70 is positioned in the containing area 20, and a fixed groove 71 is dented on said wire end storage piece 70, so that the wire end can be placed or inserted into said fixed groove 71.

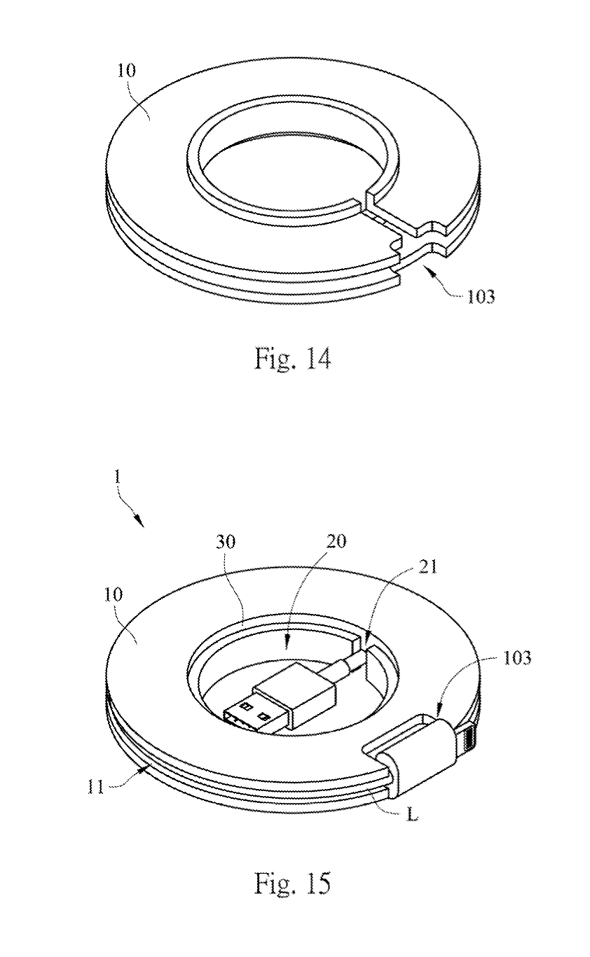

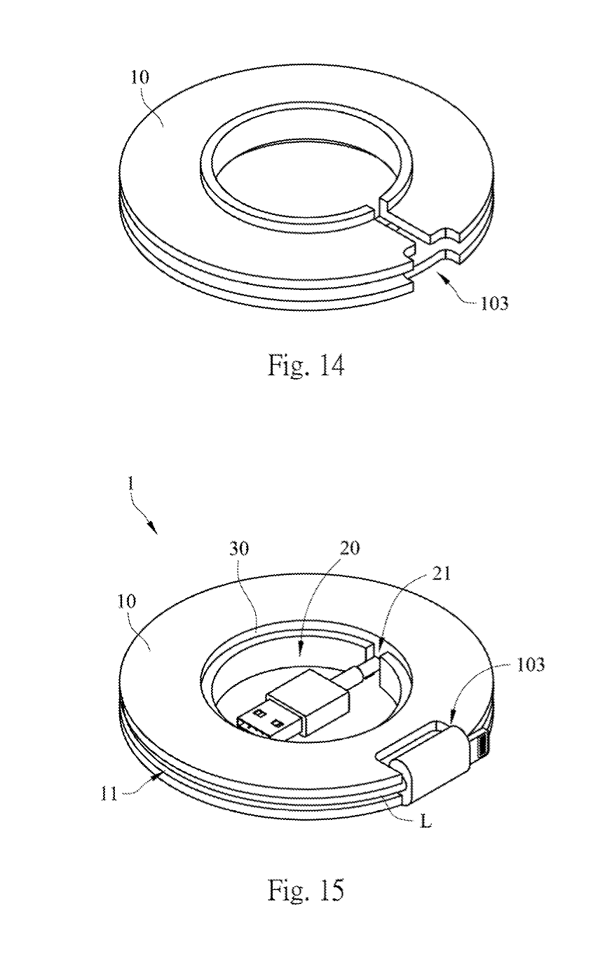

As shown in FIG. 14 and FIG. 15, a wire end fixing slot 103 is positioned at the outer side of said main body 10 in an inward concave manner. Thereby, the wire end can be inserted in this slot, so that it wouldn't wobble idly, or in other words, the wire L wouldn't leave the main body 10 randomly, and would advantageously remain in the storage part.

According to FIG. 17, which is a three dimensional schematic view incorporating a wire end storage piece 70 and a wire end fixing slot 103, by means of fixing both ends of the wire L at certain positions, even more convenience is provided in carrying the device.

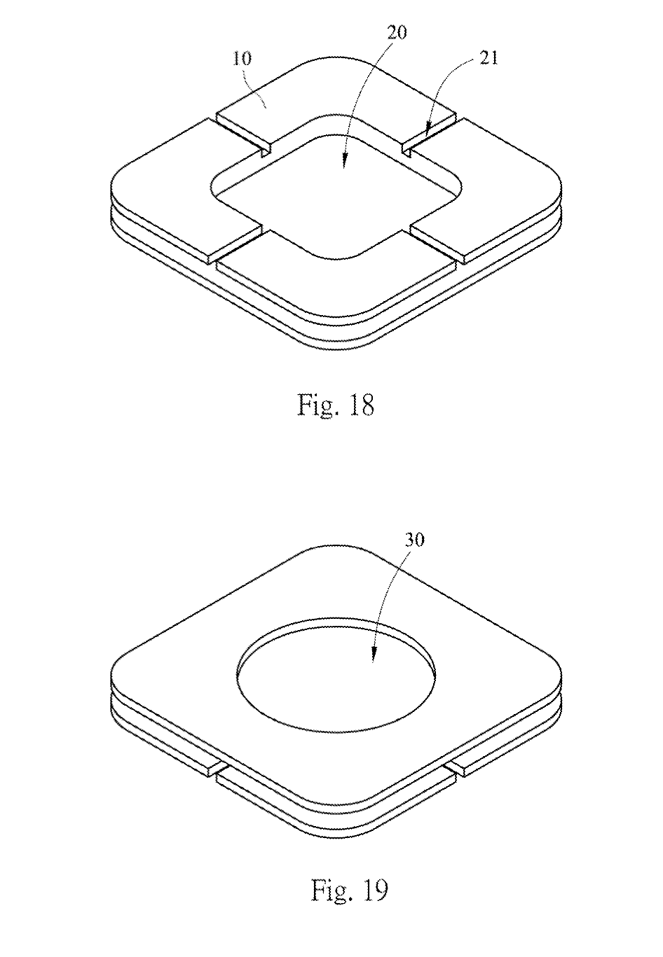

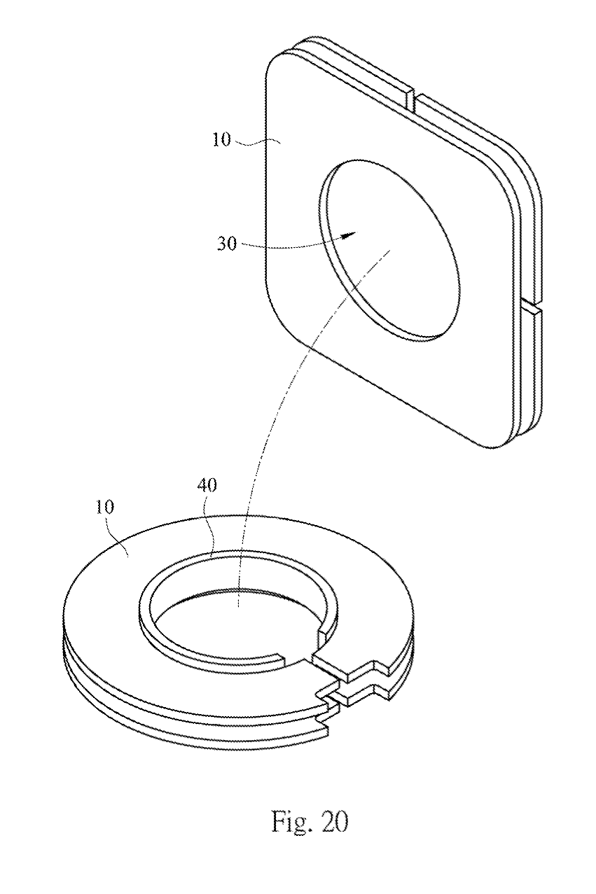

Also, the main body 10 can be square-shaped as shown in FIG. 18, so that it can be paired up with a long and narrow wire of a remote control, and the remote control can be positioned at one side of the square, and wouldn't leave the main body 10. Of course, the main body 10 can also have any shape other than the circular and square-shaped examples given in the figures, for instance it can have an oval shape. As shown in FIG. 19, its reverse side also has a corresponding fixing slot 30, so that it can be assembled with other main bodies 10. As shown in FIG. 20, this square-shaped main body 10 can be placed on top of said circular main body 10, such that the fixing piece 40 and the fixing slot 30 found at corresponding positions are inserted into each other.

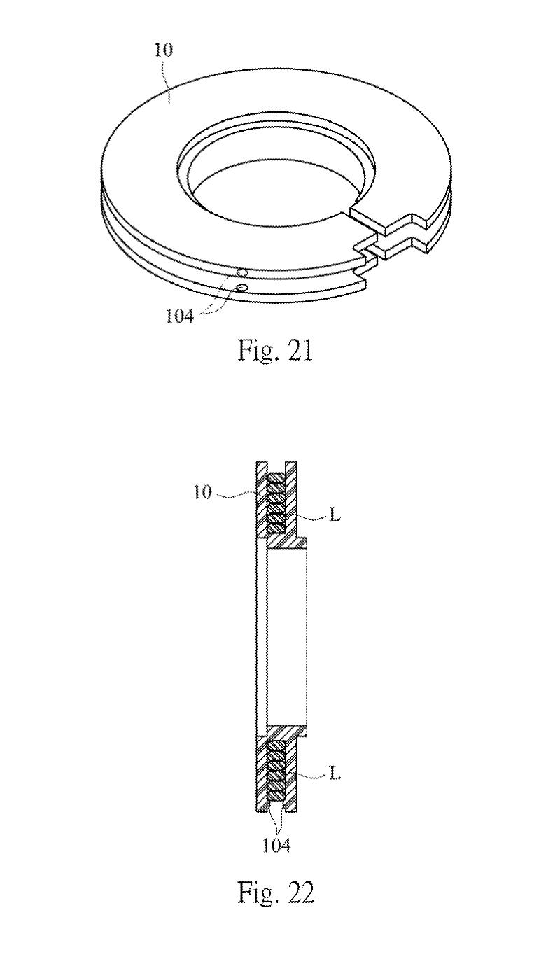

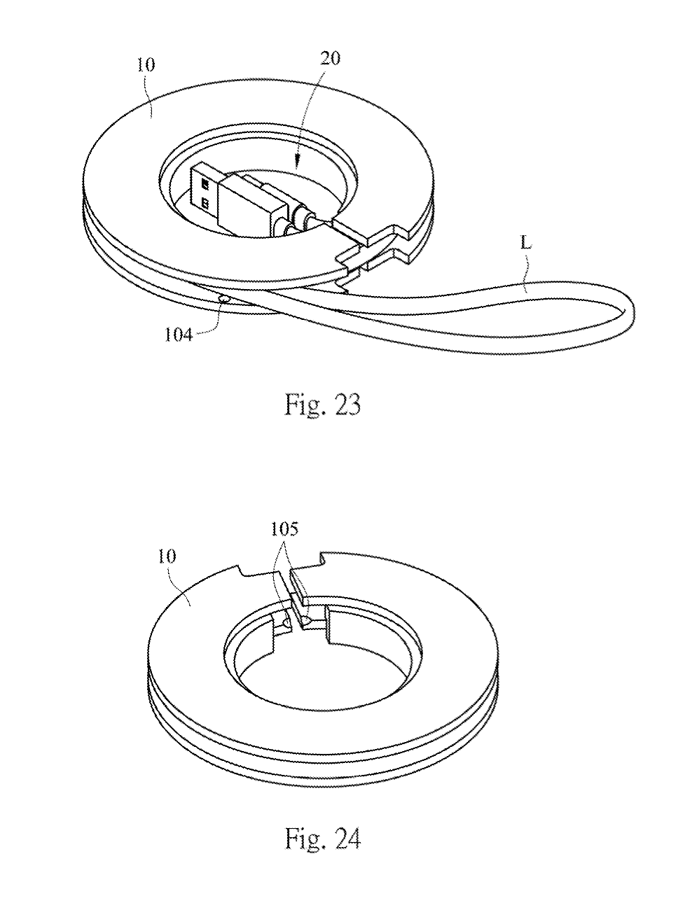

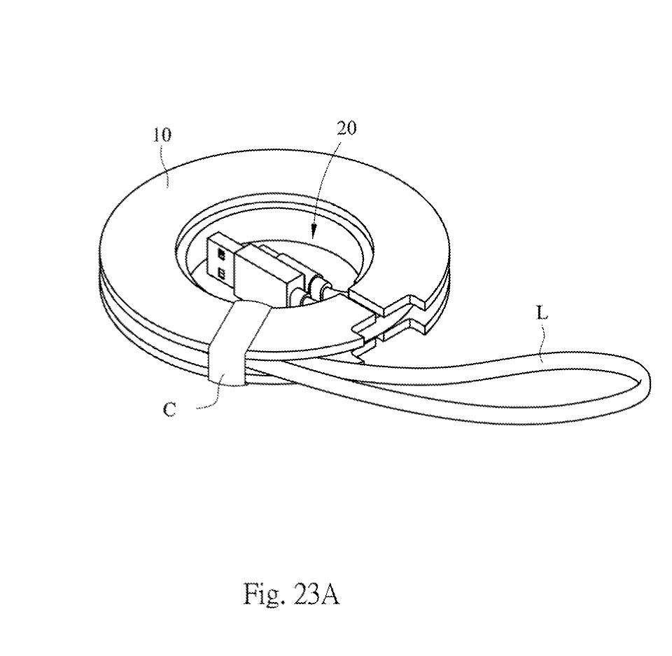

According to FIGS. 21 and 22, wherein at least two blocking pieces 104 are positioned within the groove 11 of the main body 10, after the wire L is wound, the outermost circle of the wire L is pressed against the edge of said blocking piece 104, so that the outermost circle of the wire L wouldn't be exposed out of the main body 10 due to the original elastic restoring force of the wire L. Moreover, according to FIG. 23, when the two ends of the wire L are placed together into the containing area 20, the wire L can be directly wound around the main body 10, and the part remaining outside would form a shape like a carrying handle, so that it can be held and carried by the user. Furthermore, it can be paired with the above described blocking piece 104 embodiments, so that the wire would be prevented from getting out, and the handle position would be fixed. Or, as shown in FIG. 23A, by using a C-shaped buckle C to buckle/hook the main body 10 in order to restrict the position of the wire after being wound, it would be prevented from sliding out of the main body.

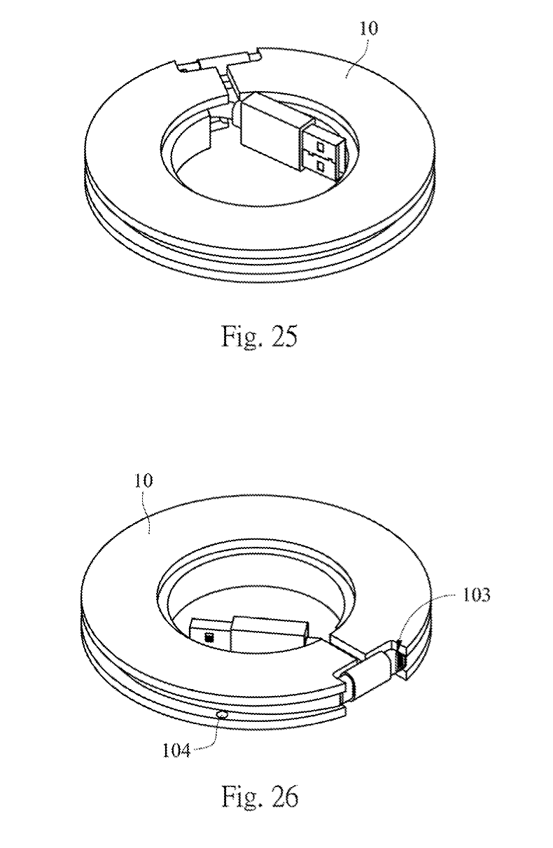

According to FIGS. 24 to 26, also a shallow groove 105 is positioned at the side of said port 21. By means of this shallow groove 105, the caliber of the port 21 becomes larger; and therefore the wire ends set included in the remainder part of the wire L would also enter into the main body 10 (and into the shallow groove 105), and at the same time, since the wire ends set would be restricted, one end of the wire L wouldn't be left idle.

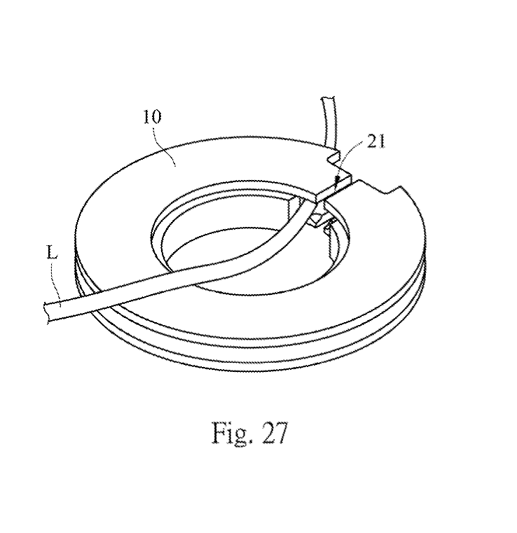

As shown in FIG. 27, after the wire L is completely unfolded, the wire L would go through the port 21, the main body 10 would press against the wire L, and the main body 10 would move along with one piece of the wire L, so that separation of the wire L and the main body 10 would be avoided in order to prevent the main body 10 from being forgotten at any place.

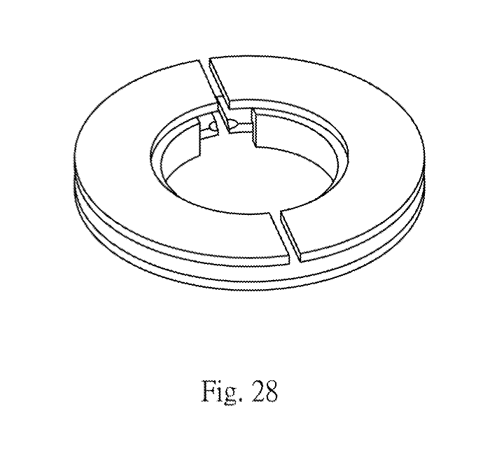

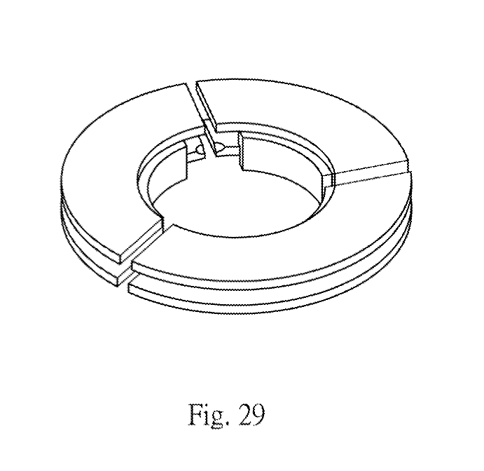

As shown in FIGS. 28 and 29, two or three ports 21 can be provided on the main body 10, so that when wires with different lengths are being wound, the other ends of the wires can be placed into the nearest port 21. As a result, the purpose of using wires with different lengths can be achieved.

Moreover, a cover body (not shown in the figures) can also be integrated onto the main body 10 to cover said containing area 20. Besides, drawings such as advertisements can be designed on the cover, so that it can be used for advertisement purposes.

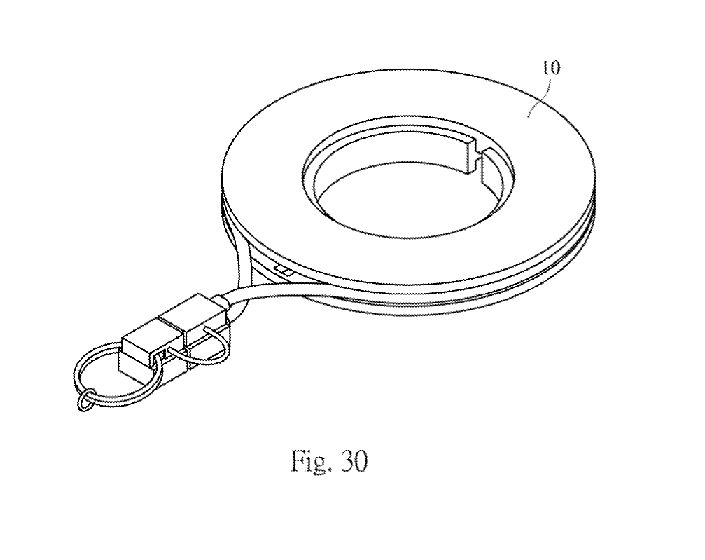

Moreover, as shown in FIG. 30, after the wire L is wound, a fixed cover comprising a key ring can be used, wherein the two ends of said wire L would be fixed together. This fixed cover can fix the positions of the two ends of the wire L, so that the wire wouldn't easily break away from the main body. Also, by means of the integrated key ring, the device can also be used for carrying keys, which makes the whole structure more useful.

What is claimed is:

1. A wire storage device, comprising:
a main body, comprising a groove at its outer side, wherein said groove surrounds said main body all the way around;
a containing area positioned at the inner side of said main body, and a port positioned at the edge of said containing area, wherein said port connects said groove with said containing area;
a fixing slot positioned at one side of said main body; and
a fixing piece positioned at the other side of said main body; such that:
one end of the wire is positioned within said containing area, and after entering into said groove via said port, the wire can be wound along said groove.

2. A wire storage device according to claim 1, wherein said containing area also includes a rechargeable battery.

3. A wire storage device according to claim 1, wherein a foot stool is also pin jointed to said main body, and a base is also pin jointed on said main body at the opposite side of said foot stool.

4. A wire storage device according to claim 3, wherein said main body also comprises a foot stool receiving slot and a base receiving slot.

5. A wire storage device according to claim 1, wherein said groove bottom becomes stair-shaped.

6. A wire storage device according to claim 1, wherein a wire end storage piece is positioned on said containing area.

7. A wire storage device according to claim 1 or 6, wherein a wire end fixing slot is dented inwards from outside of said main body.

8. A wire storage device according to claim 7, wherein at least two blocking pieces are positioned inside said groove.

9. A wire storage device according to claim 7, wherein two shallow grooves are positioned at the side of said port.

10. A wire storage device group which is formed by putting more than one wire storage devices according to claim 1 on top of each other, wherein the fixing piece of one of said wire storage devices is plugged into the fixing slot of another wire storage device.
